(19) United States
(12) Patent Application Publication
(10) Pub. No.: US 2003/0183880 A1
(43) Pub. Date: Oct. 2, 2003

(54) Semiconductor device covering transistor and resistance with capacitor material

(76) Inventors: Yoshiro Goto, Kanagawa (JP); Kiyotaka Imai, Kanagawa (JP)

Correspondence Address: Choate, Hall & Stewart, Patent Group, Exchange Place, 53 State Street, Boston, MA, 02109-2804, US

(21) Appl. No.: 10/396,787

(22) Filed: Mar. 25, 2003

(30) Foreign Application Priority Data
Mar. 27, 2002 (JP) 88443/2002

(51) Int. Cl. H01L 29/76

(52) U.S. Cl. 257/379

(57) ABSTRACT

According to a present invention, a gate electrode and a lower electrode are formed on a semiconductor substrate and a silicide layer is formed on the gate electrode and the lower electrode. Then, a capacitor insulating film functioning as an etching stopper is formed on the entire surface and a silicide layer is formed on the entire surface. After selectively forming the silicide layer to form the upper electrode and a silicide resistance element, a layer insulating film is on the entire surface and then contact holes are formed in the layer insulating film until the capacitor insulating film is exposed. Then, the capacitor insulating film is removed to expose the gate electrode, the lower electrode, the upper electrode and the resistance element.

### BACKGROUND OF THE INVENTION

1. Field of the Invention

The present invention relates to a semiconductor device and its manufacturing method, and more particularly to a semiconductor device equipped with a capacitance element, a transistor and a plurality of resistance elements and its manufacturing method.

2. Description of a Related Art

In recent years, an increase in the scale and operating speed and a reduction in the size are being desired for a semiconductor device having analog circuits formed on a semiconductor substrate. In order to meet such demands, semiconductor devices with transistors, capacitance elements and resistance elements formed mixedly on one semiconductor substrate have been provided. Such a semiconductor device has been proposed in, for example, Japanese Patent Applications Laid Open, No. Hei 11-289049.

The method of manufacturing disclosed in the publication will be described in the following.

A gate polysilicon film, a gate WSi (tungsten silicide) film, a capacitor nitride film and a capacitor WSi film are formed in this order on a transistor formation region, a metallic capacitor formation region and a resistor formation region on a semiconductor substrate. After selectively leaving the capacitor WSi film by removing the capacitor WSi film selectively, gate of the transistor, upper and lower electrodes of a capacitance element and a resistance element are formed by patterning respectively the capacitor nitride film, the gate WSi film and the gate polysilicon film, by using predetermined resist patterns corresponding to respective formation regions. Then, a source-drain region and a sidewall oxide film are formed appropriately. After that, a BPSG film is deposited on the entire surface, and contact holes corresponding to respective elements are formed by etching desired regions of the BPSG film. Metal electrodes are formed by filling the contact holes with a metal.

In this way, a transistor, a capacitance element and a resistance element consisting of polysilicon and silicide are formed.

According to this method, it is possible to form various elements in the same process. However, in forming these elements, contact holes are formed at positions corresponding to respective elements as mentioned above for connection with upper wirings, and the length (depth) of the contact holes is different because the depth of formation of respective elements are different. Because of this, if contact holes with different depths are opened simultaneously, the surface of the elements corresponding to short contact holes are overetched, resulting in a problem of deterioration in the performance of the elements, for example, the problem of an increase in the contact resistance due to the etching of silicide layer 13 of the capacitor element, polysilicon high resistance element and silicide resistance element.

### BRIEF SUMMARY OF THE INVENTION

The semiconductor device according to the present invention is equipped with a capacitance element including a capacitor insulating film, a transistor having a silicide layer, where the capacitor insulating film covers the silicide layer.

Another semiconductor device according to the invention has a transistor including a gate electrode, a capacitance element including a lower electrode formed simultaneously with the gate electrode and is silicided (namely, silicidized, meaning the formation of a silicide) and an upper electrode composed of a silicide, and a capacitor insulating film, a first resistance element formed simultaneously with the upper electrode, a second resistance element formed simultaneously with the lower electrode, and a third resistance element formed simultaneously with the lower electrode and has a higher resistance than the second silicide resistance element, where the capacitor insulating film covers the surface of at least one of the transistor and the resistance elements.

Still another semiconductor device according to the invention is equipped with a capacitance element having a capacitor insulating film, at least one of a resistance element and a transistor element, a layer insulating film formed on the upper face of at least one of the capacitance element, the resistance element and the transistor element, a first contact plug formed in the layer insulating film and connected to the capacitance element, and a second contact plug formed in the layer insulating film and connected at least to either one of the resistance element and the transistor element, where the upper face of at least one of the resistance element and the transistor element is covered with the capacitor insulating film.

The manufacturing method of a semiconductor device according to the invention includes forming a gate electrode on a semiconductor substrate, forming a diffused layer in a predetermined region of the semiconductor substrate, forming a first silicide layer on the diffused layer and the gate electrode, forming a nitride film on the entire surface, forming a second silicide layer on the entire surface, forming a photoresist on an upper electrode of a capacitance element and on the portion to be a silicide resistance element in order to form the capacitance element and a silicide resistance element, then patterning the second silicide layer, and forming a layer insulating film on the entire surface.

By the manufacturing method according to the invention in which the nitride film is formed on the entire surface after the formation of the diffused layer and the gate electrode, the nitride film can be made to serve as an etching stopper in the formation of contact holes in a later step.

Another manufacturing method of a semiconductor device according to the invention includes forming a conductive film on a semiconductor substrate, forming a first to a third conductive film patterns by patterning the conductive film, forming a first insulating film in a part of the second conductive film pattern, forming a film of a metal on the entire surface, forming a first silicide layer on the entire surface of the first and the third conductive film patterns and on the portion of the second conductive film pattern not covered with the insulating film, by bringing the metal and the conductive film into reaction through heat treatment, removing non reacted metal, forming a second insulating film on the entire surface, forming a second silicide layer on the second insulating film on the first conductive film pattern and on the second insulating film formed in the regions other than the first to the third conductive patterns, forming a third insulating film other than the second insulating film on the entire surface, forming contact holes in the third insulating film until the second insulating film formed on the first to the third conductive film patterns and the second silicide layer, and removing the second insulating film exposed by the contact holes.

By the manufacturing method of the invention in which the second insulating film is formed on the entire surface after the formation of the conductive film patterns and the first silicide layer, then the third insulating film other than the second insulating film is formed, the second insulating film can be made to serve as an etching stopper in the formation of the contact holes in the third insulating film.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIG. 1 is a schematic drawing showing an embodiment of the present invention;

FIGS. 2(a) to 2(i) are drawings showing the manufacturing method of the embodiment of the invention;

FIG. 3 is a drawing showing an example of use of the polysilicon high resistance element adopted in the invention;

FIGS. 4(a) and 4(b) are drawings showing an example of use of the capacitance element and the WSi resistance element adopted in the invention; and

FIGS. 5(a) and 5(b) are drawings showing an example of use of the silicide resistance element adopted in the invention.

### DETAILED DESCRIPTION OF THE INVENTION

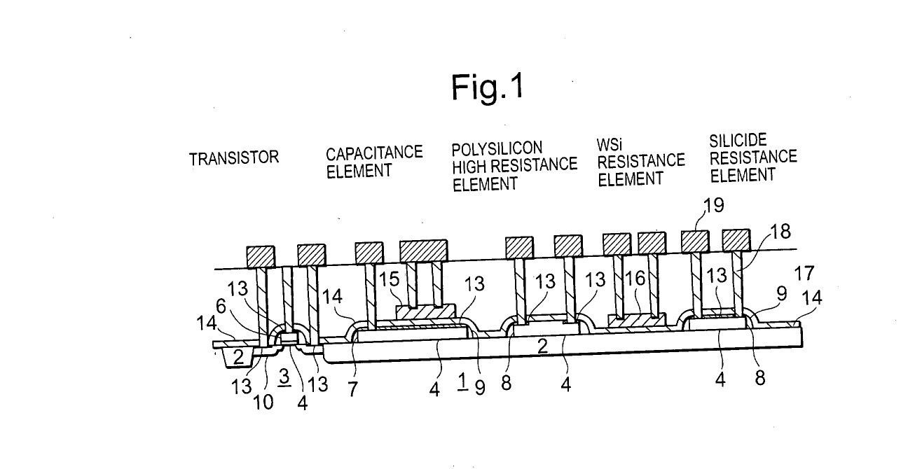

FIG. 1 is a drawing showing a first embodiment of this invention. In this embodiment, the formation of an N-type MOS transistor, a capacitance element, a polysilicon high resistance element, a tungsten silicide (WSi) resistance element and a silicide resistance element are formed on the same wafer will be described.

As shown in FIG. 1, an element isolation region 2 by which an element active region 3 is defined is formed on the surface of a silicon wafer 1 serving as a semiconductor substrate.

In the element active region an N-type MOS transistor, for example, is formed, and an N-type impurity diffused layer 10 is formed in the element active region 3 as a source-drain region of the transistor. A gate insulating film 4 and a gate electrode 6 are formed on the element active region 3, and sidewalls 9 are formed on the side faces of the gate electrode 6. A silicide layer 13 is formed on the diffused layer 10 and the gate electrode 6. Moreover, a nitride film 14, for example, is formed so as to cover the diffused layer 10, the sidewalls 9 and the gate electrode 6.

A capacitance element is formed on the element isolation region 2, and its lower electrode consists of a polysilicon layer 7 formed on the element isolation region 2 and the silicide layer 13. The nitride film 14 serving also as a capacitor insulating film is formed so as to cover the lower electrode and the sidewalls 9. An upper electrode 15 is formed in a part on the nitride film 14 formed on the lower electrode.

The polysilicon high resistance element is formed on the element isolation region 2. Silicide layers 13 and sidewalls 9 are formed on both ends of the upper face and side faces, respectively, of a polysilicon layer 8 formed on the element isolation region 2. The entire surface of the polysilicon high resistance element constituted of these parts is covered with the nitride film 14.

The WSi resistance element 16 which is formed simultaneously with the upper electrode 15 of the capacitance element, is formed on the element isolation region 2 via the nitride film 14.

In the silicide resistance element, the polysilicon layer 8 is formed on the element isolation region 2, and the silicide layer 13 is formed on the entire upper face of the polysilicon layer 8 and the sidewalls 9 are formed on its side faces. The nitride film 14 is formed so as to cover the silicide resistance element.

A layer insulating film 17 is formed on the upper face of the transistor, the capacitance element, the polysilicon high resistance element, the WSi resistance element and the silicide resistance element. Wirings 19 are formed at predetermined locations on the upper face of the film 17, and the wirings 19 and respective elements are connected electrically by contacts 18 formed in the layer insulating film 17.

The nitride film 14 in this invention is formed so as to cover all of the elements. In this embodiment, the nitride film 14 is a series of continuous film, and is covering the entire surface of respective elements and the element isolation region 2 between the elements. The nitride film 14 acts as an etching stopper in the formation of respective contact holes. Accordingly, it is possible to prevent overetching in the opening of contact holes with different depths. Although the capacitor insulating film 14 of the capacitance element in this embodiment has been described as made of a nitride film, it maybe a composite film consisting of a nitride film and an oxide film, or a composite film (ONO film) consisting of an oxide film, a nitride film and an oxide film which will be called collectively an oxynitride film. In the present specification, either of a composite film consisting of an oxide film and a nitride film, and a film of single nitride film will be referred to as a nitride film.

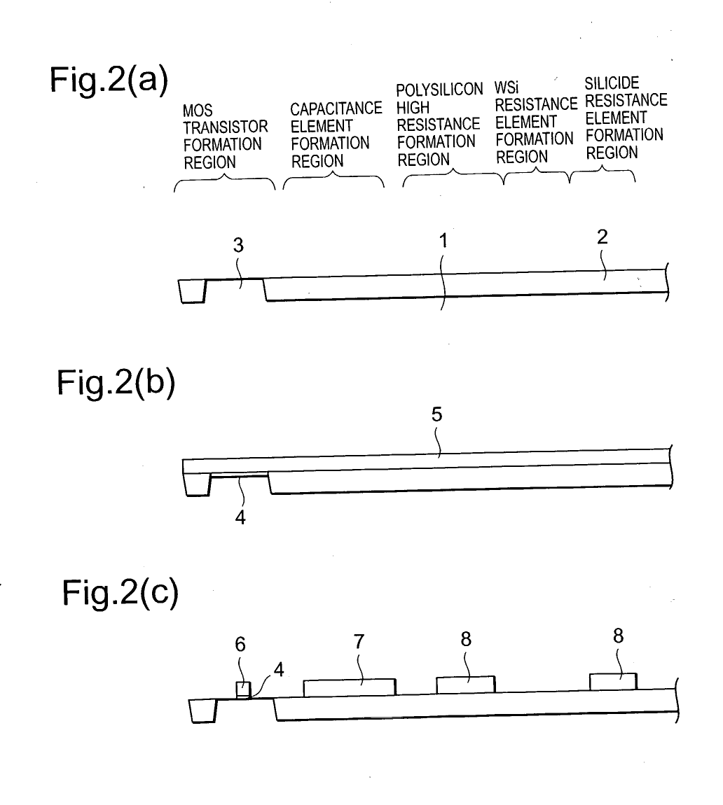

Next, referring to FIG. 2, the manufacturing method of the embodiments according to the invention will be described.

As shown in FIG. 2(a), an oxide film with a thickness of about 300.0 nm is formed on the surface of a silicon wafer 1 to serve as an element isolation region 2. The element isolation region 2 maybe formed, for example, by shallow trench isolation (STI) technique. As a result, an element active region 3 is defined.

Next, as shown in FIG. 2(b), a gate oxide film 4 and a polysilicon film 5 as a conductive film are formed. The thickness of the gate oxide film 4 is in the range of 2.0 to 5.0 nm, and the thickness of the polysilicon film 5 is in the range of 100.0 to 200.0 nm.

Next, as shown in FIG. 2(c), a gate electrode 6, a polysilicon layer 7 as a lower electrode of the capacitance element and a polysilicon layer 8 as a gate resistor are formed by patterning the polysilicon film 5 by normal lithography and dry etching techniques.

Next, as shown in FIG. 2(d), low concentration N-type impurity ions are implanted in order to form an LDD (lightly doped drain) structure of a MOS transistor. For example, arsenic of 60 keV is implanted at a dose of 5E13 particles/cm². This implantation is applied only to the MOS transistor region using an implantation resist mask (not shown). Then, an oxide film is grown on the entire surface of the silicon substrate 1 (not shown), and sidewalls 9 are formed on the side faces of the gate electrode by anisotropic etching of the oxide film. After that, a high concentration N-type impurity, for example, arsenic with 30 keV is implanted at a dose of about 5E15 particles/cm² in order to form a source and a drain of the MOS transistor. As a result an N-type diffused layer 10 to become the source and the drain are formed. The implantation of the high concentration N-type impurity for the formation of the source and the drain of the MOS transistor is applied not only to the NMOS but also to the polysilicon layer 7 as the lower electrode of the capacitance element and the polysilicon layer 8 as the gate resistor, so that these polysilicon layers are converted to N-type polysilicon layers. Here, the lower electrode 7 of the capacitance element and the polysilicon layer 8 maybe converted to P-type polysilicon layers by a P-type impurity implantation (not shown) carried out for the formation of a source and drain diffused layer for a PMOS. Since a P-type polysilicon has a smaller temperature dependence of resistance than that of an N-type polysilicon, a P-type polysilicon is preferable as polysilicon to function as a resistor.

Next, as shown in FIG. 2(e), a thin insulating film such as an oxide film 11 with a thickness of about 30 to 50 nm, for example, is formed on the entire surface of the silicon substrate. Then, a resist 12 is patterned only on the polysilicon layer 8 which is to become a high resistance element. Of the polysilicon layer 8, resist pattern is not formed on the region where a contact hole is to be formed later. After that, the thin oxide film 11 is etched anisotropically with the resist pattern 12 as a mask, leaving the sidewalls 9. Following that, the resist pattern 12 is removed. Next, cobalt (Co) is sputtered on the entire surface of the silicon substrate 1 to about 10.0 nm (not shown). Then, a silicide layer is formed by bringing cobalt and silicon into reaction by heating. The region where a polysilicon high resistance element is to be formed will not be silicided because of the presence of the thin oxide film 11. After that, nonreacted Co on the oxide film is removed by wet etching. In this way, as shown in FIG. 2(f), a silicide film 13 is formed on the source and drain diffused layer and on the polysilicon layer. In this case, in place of Co, a metal which has a property of forming a silicide by reaction with Si, such as titanium (Ti) or nickel (Ni), particularly as a high melting point metal, may also be adopted.

Next, as shown in FIG. 2(g), an insulating film, for example, a nitride film 14 with thickness in the range of 10.0 to 50.0 nm is formed on the entire surface of the silicon substrate 1. The growth of the nitride film is carried out by normal chemical vapor deposition (CVD) method at a temperature in the range of 700 to 750° C. Because of the generation of high temperature heat, it can produce a dense nitride film with excellent leakage characteristic can be obtained.

Following that, as shown in FIG. 2(h), a silicide, such as tungsten silicide WSi, is grown on the entire surface by CVD method, and by patterned it using a photoresist and anisotropic etching an upper electrode 15 of the capacitor and a WSi resistor 16 are formed.

Finally, as shown in FIG. 2(i), a layer insulating film 17, being an oxide film or a BPSG film, is formed. The surface of the layer insulating film may be planarized by means of chemical mechanical polishing (CMP). Then, contact holes are opened by etching the layer insulating film 17 at desired locations. In the contact hole formation, since the nitride film 14 serves as an etching stopper, the etching is stopped at the nitride film 14. After that, the diffused layer and the polysilicon layer are exposed by etching the nitride film 14. By forming the etching stopper layer on the entire surface of the substrate, it is possible to etch contact holes above the diffused layer and the polysilicon layer exactly as desired. Then, contact plugs 18, made of metal wirings 19 of copper, for example, are formed.

As described in the above, in this invention, a nitride film is provided between the upper and lower electrodes of the capacitance element, and moreover, the nitride film is made to serve as an etching stopper film in the dry etching for opening the contact holes. Namely, even when various contact holes with different heights exist mixed, etching stops once at the nitride film, then the nitride film alone is etched further, so that it is possible to prevent overetching even in shallow contact holes. Furthermore, the nitride film has a twice as large dielectric constant compared with the oxide film, so that a desired capacity can be obtained with a smaller area compared with the case of using an oxide film as the insulating film between the electrodes of the capacitance element.

Moreover, since the lower electrode of the capacitance element is silicided using Co, and the upper electrode is composed of WSi, even when a voltage is applied between the upper and lower electrodes, no spreading of a depletion layer within the electrode takes place, as occurs in the case of using a polysilicon film, making it possible to obtain a stabilized capacitance. In addition, since the upper and lower electrodes of the capacity possess low resistance equivalent to those of metals, the margin in the design of a high frequency circuit can be expanded. Besides, since the WSi resistor can be realized in the same process as the formation of WSi for the upper electrode, the manhours for element formation do not increase either.

Furthermore, according to the first embodiment, a resistance element having three kinds of sheet resistance covering the range of two orders of magnitude, namely, a gate silicide resistance element composed of silicided polysilicon having a sheet resistance of 3 to 200, for example, about 5 Ω, a WSi resistance element having sheet resistance of 30 to 80 Ω, for example, about 50 Ω, and a nonsilicided high resistance polysilicon resistance element having a sheet resistance of 300 to 700Ω, for example, about 500Ω, can be formed.

As described in the above, according to the present embodiment, it is possible to realize a capacitance element and three kinds of resistance elements having resistances covering a broad range, needed for the design of an analog circuit. Moreover, the additional manhours can be reduced compared with an MIM capacitance element formed between wiring layers, and it has also an advantage in that the silicide resistance element can be formed simultaneously with the formation of the capacitance element.

Besides, it is so arranged that the polysilicon high resistance element forms a silicide at the portion where it makes contact with the plug of the contact hole. This is for lowering the contact resistance between the contact plug and polysilicon, and the contact resistance can be reduced by about one order of magnitude compared with the case when it is not silicided. Needless to say, if the design adopted is such that the contact resistance is negligible, silicidation of the contact part is not necessarily required.

Next, the usage of the polysilicon high resistance element, the WSi resistance element and the silicide resistance element of this invention will be described.

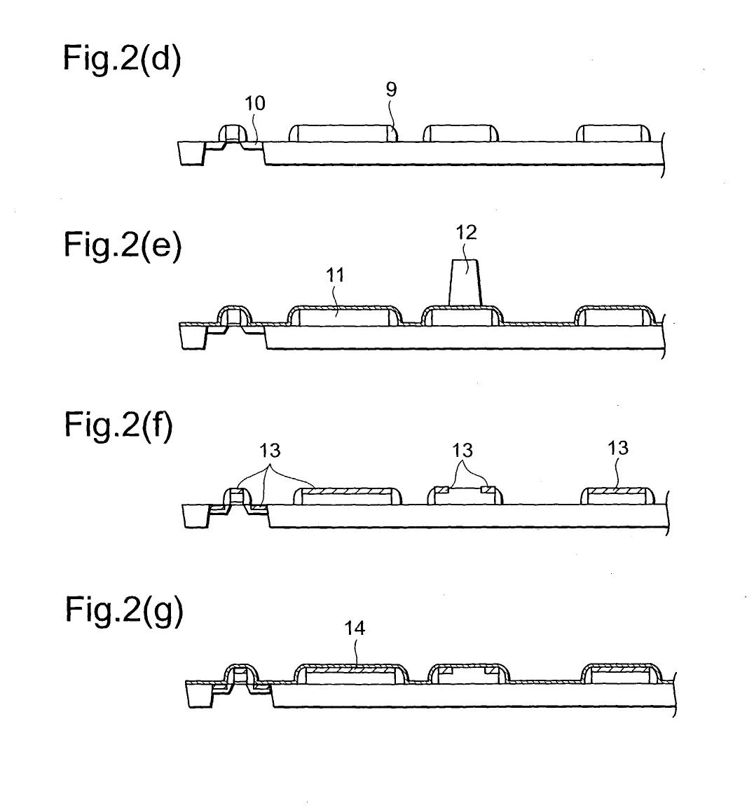

FIG. 3 is a drawing showing a source grounded amplifier circuit. The amplification factor Av of the output voltage Vout with respect to the input voltage Vin is determined by the mutual conductance gm multiplied by the load resistance R_{L}. In other words, the amplification factor of the amplifier circuit is increased for larger resistance of the resistor R_{L}. The polysilicon high resistance element (300 to 700 Ω) of this invention is used for the resistor R_{L}.

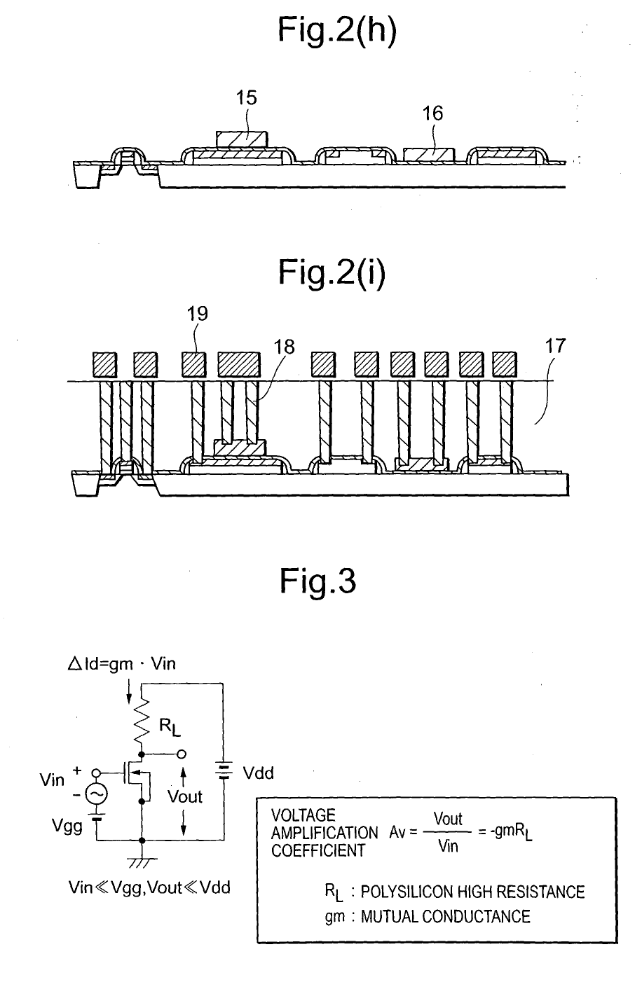

FIGS. 4(a) and (b) are simplified drawings showing a DC filter. A circuit 1 and a circuit 2 are connected by a capacitance element C alone. No DC current flows between the circuits. On the other hand, AC signals can flow between the circuit 1 and the circuit 2 by the intermediary of the capacitance element C. A high precision capacitance element of this invention is used for the capacitance element C (FIG. 4(a)). Moreover, if impedance matching between the circuit 1 and the circuit 2 is required, the WSi resistance element of this invention is used within the circuit (FIG. 4(b)).

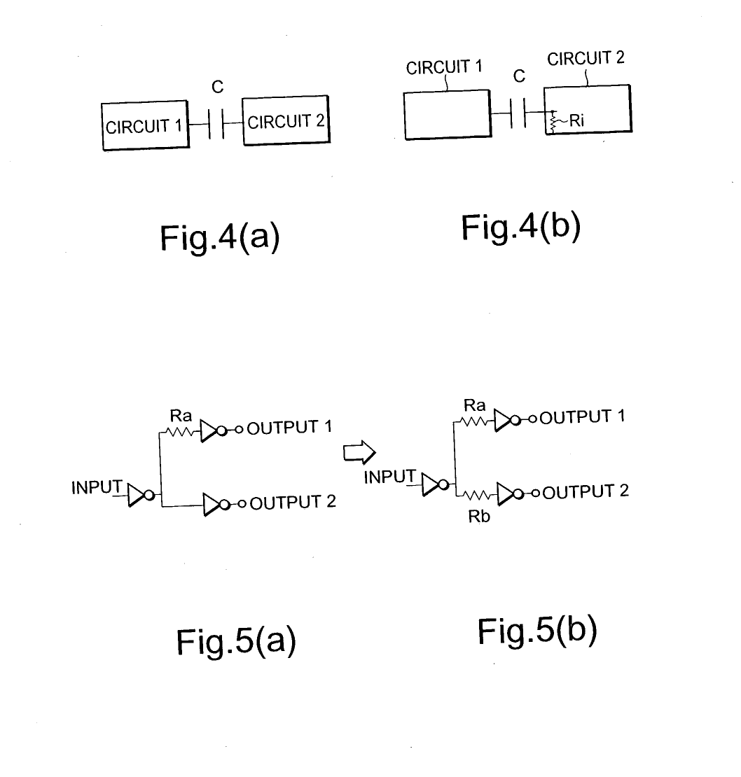

FIGS. 5(a) and (b) are simplified drawings showing a logic circuit having a configuration in which an input signal enters an inverter and its output is connected to two inverters. If one of the two outputs of the inverters, output 1, is located farther away from the inverter receiving the input compared with the other output, output 2, for the reason of layout, the wiring resistance of the first inverter is no longer negligible, and a timing deviation will be generated between the output 1 and the output 2. In order to adjust (delay) the timing of the output 2, a resistor Rb is inserted before the second inverter. The silicide resistor (with a resistance in the range of 3 to 20 Ω) of this invention is used for the resistor Rb.

In this manner, the silicide resistance element having a very low resistance (3 to 20 Ω), the polysilicon high resistance element having a very high resistance (300 to 700 Ω), the WSi resistance element having an intermediate resistance and the high precision capacitance element C are used in an analog or digital circuit on one chip.

The present invention is not limited to the above embodiments, and can be executed with modifications in various ways within the scope of the invention. For example, although the elements according to the invention are arranged in the order from the left, a transistor, a capacitance element, a polysilicon high resistance element, a WSi resistance element and a silicide resistance element, the layout need not be limited to this arrangement, and their positions, order, layout and size may be changed appropriately. Moreover, the example of using a nitride film as an etching stopper has been described in this invention, but the use is not limited to this example. Any other film that can function as a capacitor insulating film and can act as an etching stopper to the layer insulating film may be adopted. For example, films of SiC and SiCN may be mentioned other than a nitride film (Si₃N₄) and an oxynitride film (SiON).

As in the above, according to the present invention, a nitride film is used as the capacitor insulating film for the capacitance element, and make the nitride film serve as the etching stopper film in the formation of contact holes in a later process by depositing the nitride film on the surface of the other elements. As a result, precise contact holes can be formed as needed even if contact holes with different lengths are to be formed mixedly. Consequently, according to the invention it is possible to provide a semiconductor device with high reliability.

Moreover, according to the invention, the polysilicon high resistance element and the silicide resistance element can be formed simultaneously with the formation of polysilicon and silicide as the lower electrode of the capacitance element, so that processes for the formation of these resistance elements can be reduced.

Furthermore, according to the invention, the WSi resistance element is formed simultaneously with the formation of WSi as the upper electrode for the capacitance element, so that the process for its manufacture can be reduced.

We can request features relating to a method of a present invention as claims with the follow definition.

A manufacturing method of a semiconductor device comprising:

forming a gate electrode and a lower electrode of a capacitor on a substrate;

forming a diffused region in a portion of said semiconductor substrate;

forming a first silicide layer on said diffused layer, said gate electrode and lower electrode;

forming a nitride film on the entire surface;

selectively forming a second silicide layer as a upper electrode on said nitride film over said lower electrode and a third silicide layer as a first resistor on said substrate; and

forming a layer insulating film on the entire surface.

The method further comprising forming contact holes in said layer insulating film to expose said nitride film;

removing said nitride film to expose the surfaces of said lower electrode, said upper electrode, said gate electrode and said diffused region.

The method wherein

when said gate electrode and a lower electrode is formed, first and second conductive film are formed to be formed a second resistor and a third resistor, respectively;

when said first silicide layer is formed, said first slicide layer is formed on said second conductive film;

when said nitride film is formed, said nitride film covers said first and second conducive film.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims cover any modifications or embodiments as fall within the true scope of the invention.

What is claimed is:

1. A semiconductor device, comprising:
a resistance element having a slicide layer;
a transistor element having a silicide layer thereon;
a capacitance element having a lower electrode, a upper electrode and a capacitor insulating film between said lower and upper electrode, said lower electrode having a silicide layer thereon, said upper electrode composed of a silicide layer;
said capacitor insulating film covering said silicide layers of said resistance and transistor elements;
a layer insulating film formed on said upper electrode of said capacitance element and formed on said capacitor insulating film covering said silicide layers of said resistance and transistor elements;
a plurality of contact holes formed in said layer insulating film, each of which exposes said silicide layers of said capacitance element, said resistance and transistor elements; and
a plurality of contact plugs formed in said contact holes.

2. The semiconductor device as claimed in claim 1, wherein said transistor element has a gate electrode of the same layer with said lower electrode.

3. The semiconductor device as claimed in claim 1, wherein said resistance element is equipped with a resistor layer of the same layer with said lower electrode.

4. The semiconductor device as claimed in claim 1, wherein and said resistance element is equipped with said second silicide layer of the same layer with said upper electrode.

5. The semiconductor device as claimed in claim 1, wherein said resistance element is equipped with a first resistor of the same layer with said lower electrode and a second resistor of the same layer with said upper electrode.

6. The semiconductor device as claimed in claim 1, wherein said resistance element is equipped with a first resistor of the same layer with said lower electrode and having a silicide layer on its entire upper face, a second resistor of the same layer with said lower electrode and having a silicide layer only in the contact part, and a third resistor of the same layer with said upper electrode.

7. The semiconductor device as claimed in claim 6, wherein said first resistor is for constituting a logic circuit, said second resistor is for constituting an amplifier circuit, and said third resistor is used for impedance matching.

8. A semiconductor device, comprising:
a transistor formed on a substrate; and
a capacitance element formed on said substrate, said capacitance element having a capacitor insulating film, said capacitor insulating film being covering a portion of said transistor.

9. The device as claimed in claim 8, further comprising:
a first resistor formed on said substrate, said capacitor insulating film covering a portion of said first resistor.

10. The device as claimed in claim 9, further comprising:
a second resistor formed on said substrate and a silicide layer thereon, said capacitor insulating film covering a portion of said second resistor.

11. The device as claimed in claim 10, further comprising:
a third resistor formed on said substrate, said third resistor being formed on said capacitor insulating film.

12. The device as claimed in claim 11, wherein said first resistor has no silicide portion at its top surface.

13. The device as claimed in claim 12, wherein said transistor has a silicided diffusion layer, said capacitor insulating film directly formed on said silicided diffusion layer.

14. A semiconductor device, comprising:
a transistor having a gate electrode relating to a first layer;
a capacitance element including a silicided lower electrode relating to said first layer, an upper electrode composed of a silicide, and a capacitor insulating film formed between said silicided lower electrode and said upper electrode;
a first resistance element relating to said upper electrode;
a second resistance element relating to said lower electrode; and
a third resistance element relating to said lower electrode and having a resistance higher than that of said second resistance element;
wherein said capacitor insulating film covers the surface of at least one of said transistor and said second and third resistance elements.

15. The semiconductor device as claimed in claim 15, wherein said third resistance element has silicide portions and no silicide portion between said silicide portions at its top surface and said first and second resistance elements each has a silicide potion at its entire top surface.
